(19) United States
(12) Patent Application Publication
(10) Pub. No.: US 2009/0231151 A1
(43) Pub. Date: Sep. 17, 2009

(54) Method for Monitoring the Carrying Capacity of Steel-Concrete Structures

(76) Inventor: Igor Gennadievich Korolev, Moscow (RU)

Correspondence Address: Aleksandr Smushkovich, POB 140505, Brooklyn, NY, 11214, US

(21) Appl. No.: 11/920,948

(22) PCT Filed: Apr. 11, 2007
(86) PCT No.: PCT/RU2007/000173

§ 371 Date: Nov. 23, 2007

(30) Foreign Application Priority Data
Mar. 2, 2006 (RU) 2006106390

(51) Int. Cl. G08B 21/00; G01R 27/08

(52) U.S. Cl. 340/657; 324/691

(57) ABSTRACT

A method for monitoring and estimating the carrying capacity of a pre-stressed ferromagnetic metal armature element of a metal-concrete load-bearing structure is proposed, comprising the steps of: preliminary calibrating the element by passing electric current therethrough and measuring its electrical resistance with respect to the tension stress applied to the element, determination of an ultimate resistance value corresponding to a predetermined ultimate limit stress value permitted to the element, saving the ultimate resistance value in a computer memory, passing electric current through the element during construction or exploitation of the load-bearing structure being in a loaded state, measuring altered resistance of the element, comparing the altered resistance with the ultimate resistance value, and warning when the altered resistance reaching the ultimate resistance value. Additional embodiments disclose deployment of two types of electric current: alternating and direct. The method allows significantly increasing safety of metal-concrete structures and reducing electric energy consumption.

### CROSS-REFERENCE TO RELATED APPLICATIONS

This application is a U.S. national phase application of a PCT application PCT/RU2006/000173 filed on 11 Apr. 2007, published as WO2007/102754, whose disclosure is incorporated herein in its entirety by reference, which PCT application claims priority of a Russian patent application RU2006/106390 filed on 2 Mar. 2006.

### FIELD OF THE INVENTION

The invention relates to non-destructive methods of control and monitoring the quality and carrying capacity of pre-stressed metal-concrete structures, such as a roof or floor, particularly to estimating a tense-deformation state of armature of overhead covers and floors. The invention can be used for building and structure monitoring.

### BACKGROUND OF THE INVENTION

A method of underground metal structure insulating cover condition monitoring by passing of high frequency alternating current through the metallic structure-grounding anode circuit is known in the art, wherein during the exploitation period of the building, dielectric dissipation (tangent of the dissipation angle) is measured, and a coefficient of ageing of the insulating cover is calculated (Applicant's inventor certificate of the USSR No. 725006, class G01N 27/02, BI No. 12, 30.03.80).

There is known in the art a method of measurement of a tense state of metal construction elements of a nuclear power installation by measuring its electrical resistance alteration (Application of the Russian Federation No. 2004112734, class G01N 27/02, 2005.10.20).

Furthermore, a magnetostriction method of measuring tension stress in a steel-concrete structure is known in the art, which constitutes measurement of elastic anisotropy alterations in the structure's steel armature during the process of moving the structure inside a ring-shaped inductive tension-stress sensor due to excitation of eddy currents in the armature. (Applicant's certificate No. 306409, class G01N 27/02, BI No. 19 11.06.1971 (prototype)).

The shortcomings of the above known methods are the impossibility to perform continuous monitoring the state of the armature during the process of loading the steel-concrete structure due to the necessity of providing high voltage in the monitored object, high energy consumption, as well as complexity and insufficient safety of the work process.

### BRIEF SUMMARY OF THE INVENTION

A solution to the aforementioned technical problem, proposed by the present invention is a providing of continuous monitoring and obtaining real-time information on the carrying capacity of steel-concrete overhead covers and floors according to a tense-deformation state of their armature during the construction and exploitation of buildings with reduction of energy consumption and improvement of safety.

This technical problem is solved by a method with features as claimed in an independent claim appended hereto. Further embodiments of the invention are subject to dependent claims following the independent claim.

According to the invention, the method of estimating and monitoring the quality and carrying capacity of pre-stressed metal-concrete structures of a building, such as a roof, floor or any load-bearing structure is characterized in that each element of armature of the structures (such as a steel bar, strand, or cable) is pre-calibrated with respect to stretch stress (defined as a force per unit area) and electrical resistance corresponding thereto, and during the construction and exploitation of the building at the time of loading of the metal-concrete structures, electric current is passed through each such element, alterations of its electric resistance are measured, the tense-deformation (stressed) state of the element is determined, and the carrying capacity of the structures is estimated based on a maximum permitted (ultimate) stress limit of the element. The electric current can be alternating or direct current.

The proposed method is different from the known methods in that the electrical resistance of every armature element, such as a steel bar or reinforcement cable, is preliminarily calibrated with respect to its tension stress and an ultimate resistance value for an ultimate stress limit for each armature element is determined, and during the process of construction and use of a building, while any load-bearing structure, such as an overhead cover, a roof, or a floor, is being loaded, electrical current is conducted through each loaded armature element, and the electrical resistance alteration of each armature element is monitored, which indicates the stressed state of the armature element, wherein the carrying capacity of the load-bearing structure can be estimated by comparing the altered electrical resistance with the ultimate resistance value of the stress limit for the armature element.

The proposed method, namely, the preliminary calibration of the armature elements, e.g. reinforcement bars or strands, during the conducting of electrical current, will enable, even with the help of a simple monitoring computer program, providing the possibility of detection of the ultimate stress limit, and the warning of an emergency situation of collapse of building structures, during the process of construction and use of the buildings and load-bearing structures.

The method makes use of ferromagnetic magnetostriction (reinforcement bars, strands, and cables of armature are typically made of ferromagnetic materials) that is conditioned by a complicated random dependence of elastic anisotropy alteration of the steel-concrete structure's reinforcement elements and the resistance R (ohm) to the passing electrical current, upon the stretch tension stress σ(kg/cm²), which stress induces electromotive force in the ferromagnetic. The randomness of the dependence of R upon σ derives from random magnetic properties of rolled and stretched batches of building armature elements. While the reinforcement armature element is being stretched within the elastic stage, the electrical resistance of the armature decreases almost proportionally to the mechanical tension stress due to an additional electromotive force caused by a ferromagnetic polar charged domain forced aligning along the vector of application of the stretching force. The effect is clearly observed when the electrical current passes through a tension-loaded reinforcement bar or strand.

Therefore, the inventive method for monitoring and estimating the carrying capacity of a pre-stressed ferromagnetic metal armature element of a metal-concrete load-bearing structure comprises the following steps: —preliminary calibrating the element by passing electric current therethrough and measuring its electrical resistance with respect to the tension stress applied to said element; —determination of an ultimate resistance value corresponding to a predetermined ultimate limit stress value permitted to said element; —saving the ultimate resistance value in a computer memory; —passing electric current through said element during construction or exploitation of said load-bearing structure being in a loaded state; —measuring altered resistance of said element; —comparing the altered resistance with said ultimate resistance value; and —warning when the altered resistance reaching said ultimate resistance value. Additional embodiments disclose deployment of two types of electric current: alternating and direct. The method allows significantly increasing safety of metal-concrete structures and reducing electric energy consumption.

### BRIEF DESCRIPTION OF THE DRAWINGS

FIG. 1 shows a connection diagram of preliminary stressed reinforcement bars of a hanging overhead cover;

FIG. 2 shows a scheme for calibration of a reinforcement bar;

FIG. 3 shows a graph of an electrical resistance R (ohm) dependence upon stretched stress σ(kg/cm²) applied to a reinforcement bar, wherein: R_{U} is an ultimate value of electrical resistance, σ₀₂ is an ultimate stress limit according to standard GOST 10884-94 for each grade of steel, σ_{EL} is a stress value within the elasticity stage (wherein the bar returns to its original state after having been stretched by a force), σ_{PL} is a stress value within the plasticity stage (wherein the bar is permanently deformed by a force without breaking), and σ_{CR} is a critical (breaking) stress value of the reinforcement bar.

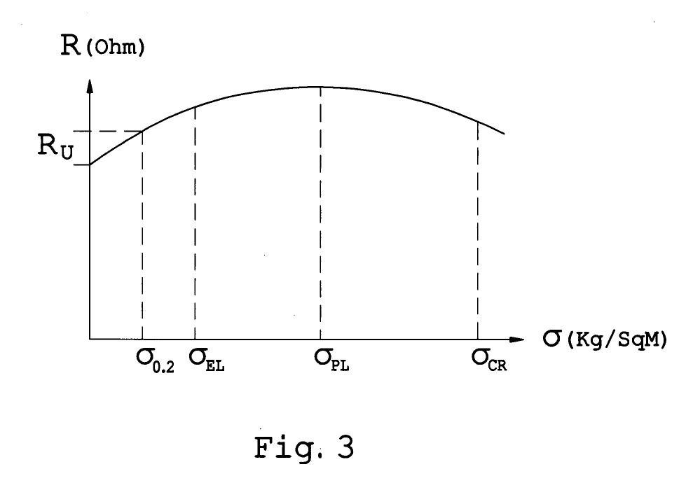

### DESCRIPTION OF PREFERRED EMBODIMENTS OF THE INVENTION

While the invention may be susceptible to embodiment in different forms, there is shown in the drawings, and will be described in detail herein, a specific embodiment of the present invention, with the understanding that the present disclosure is to be considered an exemplification of the principles of the invention, and is not intended to limit the invention to that as illustrated and described herein.

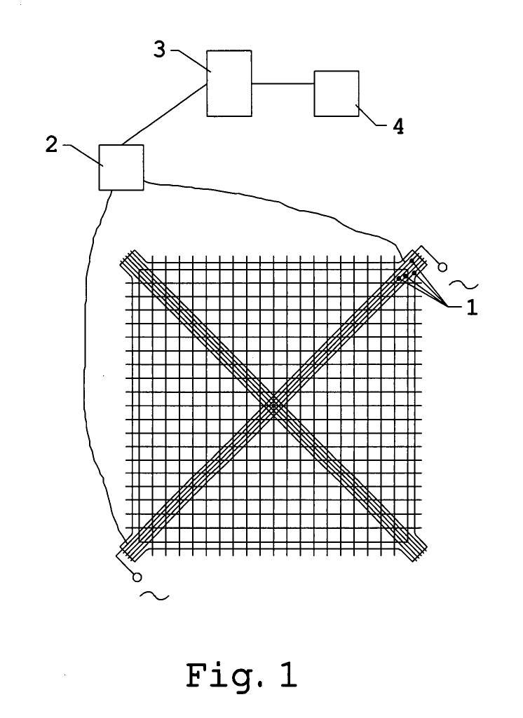

A preferred embodiment of the invention is shown on the scheme of FIG. 1. Preliminary stretched armature elements (cables, reinforcement bars, or strands of a roof or floor) 1 are connected to an electrical current power source (whose terminals are indicated as wave lines) and, through an ohmmeter 2, the armature elements 1 are also connected to a logger 3 (essentially a preprogrammed computer) and an alarm 4. While being calibrated, the armature element 1 is connected to the alternating current power source through a current regulator 5, an amplifier 6, and the ohmmeter 2.

When constructing and using load-bearing structures of large-span buildings during the loading of roof slabs and intermediate floors overhead covers, spatial curvilinear reinforced concrete shells and spatial curvilinear reinforced concrete shells with a pre-stressed self-regulated system-reinforcement web, it will be enough to run a predeterminedly low electrical current through reinforcement bars and strands of the structures, so that it is possible to monitor electrical resistance in each bar or strand with the help of the logger 3 (shown on FIG. 1). For this purpose the electrical resistance of the steel bars or cables used for construction of the roofs and floors is preliminarily calibrated with respect to the tension stress for each such bar or cable. Each value of ultimate tension stress σ₀₂ (kg/cm²) developing in the bars and strands during the exploitation will be matched with a predetermined value R_{U} (ohm) different for every bar (strand) and defined by the logger 3 as a signal (emergency) value.

The proposed technology according to the invention provides the possibility to control physical parameters of buildings during assembling operations and exploitation of constructed cast-in-place reinforced concrete large-span structures under:

A) extreme exploitation conditions of nuclear and traditional hydrocarbon fueled power stations, pools, aqua-parks, bath rooms, where there are significant sharp changes of temperature and humidity, and consequently additional thermal deformations and tensions take place, which causes strict requirements to corrosion resistance of the pre-stressed armature elements (bars and strands).

B) critical-mission (strategic) exploitation conditions e.g. in apartment houses, public and social buildings, sports buildings, where immediate evacuation of people is necessary in case of emergency of the building's structure.

### EXAMPLE OF INDUSTRIAL APPLICATION

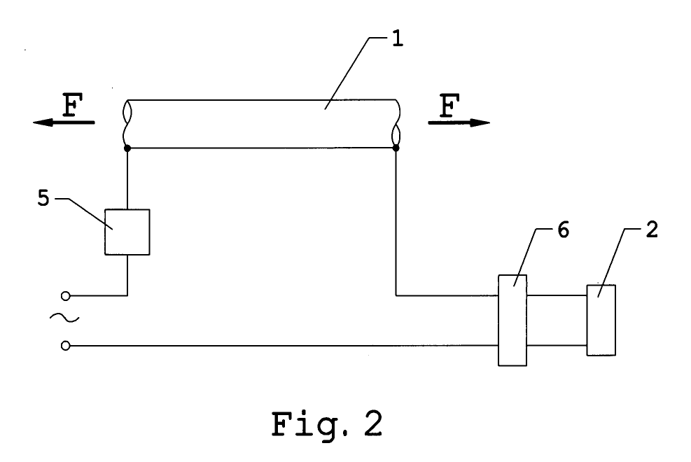

FIG. 1 depicts armature structure elements (e.g., steel multi-strand cables) 1. Before constructing a roof or floor with pre-stressed cables 1 extended along diagonals, each cable 1 is calibrated according the scheme of FIG. 2. A stretching force F (kg/cm²) is applied to the cable, and an electrical resistance R of a circuit comprising: the strand 1-current regulator 5-amplifier 6-ohmmeter 2 is being measured. The ultimate value of the electric resistance R_{U} is registered at a point when the tension stress is equal to the ultimate stress limit σ₀₂ according to standard GOST 10884-94 for each grade of steel. The calibration data are stored in the memory of logger 3 as the ultimate limit values of electrical resistance R_{U}. During the exploitation of the roof or floor, while it is being loaded, the electric current passes through every strand of the cable. At the moment when the ultimate resistance value R_{U} is reached, the alarm 4 switches on.

The proposed method provides an electronic three-dimensional system of control over mechanical stresses of any reinforced concrete structure and continuous diagnostics of emergency conditions of load-bearing structures of constructions and buildings and their stressed state both in the pre-stressed self-regulated system-reinforcement web, and in separate armature steel bars or cables, which are loaded in shape-forming layers of concrete in load-bearing reinforced concrete constructions at the diagonal and orthogonal directions, for the areas with the most intense moments of bending forces (with respect to the bending moment curve) with the use of the ferromagnetic magnetostriction effect. The on-line real-time data registered by the logger 3 gives the opportunity of preventing a building or structure collapse or evacuating the inhabitants to safe areas.

1. A method for monitoring and estimating the carrying capacity of a pre-stressed ferromagnetic metal armature element of a metal-concrete load-bearing structure comprising the steps of:
preliminary calibrating the element by passing electric current therethrough and measuring its electrical resistance with respect to the tension stress applied to said element;
determination of an ultimate resistance value corresponding to a predetermined ultimate limit stress value permitted to said element;
saving the ultimate resistance value in a computer memory;
passing electric current through said element during construction or exploitation of said load-bearing structure being in a loaded state;
measuring altered resistance of said element;
comparing the altered resistance with said ultimate resistance value; and
warning when the altered resistance reaching said ultimate resistance value.

2. The method according to claim 1, wherein said electric current being an alternating current.

3. The method according to claim 1, wherein said electric current being a direct current.
